(19) United States
(12) Patent Application Publication
(10) Pub. No.: US 2013/0000701 A1
(43) Pub. Date: Jan. 3, 2013

(54) CURVED MODULE CONTAINING PHOTOVOLTAIC CELLS

(75) Inventors: Béatrice Mottelet, Compiegne (FR); Adèle Verrat-Debailleul, Villers Sur Coudun (FR)

(73) Assignee: SAINT-GOBAIN GLASS FRANCE, Courbevoie (FR)

(21) Appl. No.: 13/514,732

(22) PCT Filed: Dec. 6, 2010
(86) PCT No.: PCT/FR2010/052611

§ 371 Date: Aug. 14, 2012

(30) Foreign Application Priority Data
Dec. 8, 2009 (FR) 0958727

(51) Int. Cl. H01L 31/048; H01L 31/18

(52) U.S. Cl. 136/251; 438/64; 257/E31.117

(57) ABSTRACT

A module made of transparent polymer material in which rectangular photovoltaic cells are embedded. The sides of the photovoltaic cells are of length l₁ and l₂ of respective perpendicular directions d₁ and d₂, according to which the module has a curvature of radius R₁, respectively R₂, and eₜ denotes the total thickness of polymer material and eₛᵤₚ the minimum thickness of polymer material covering the photovoltaic cells of the side intended to be oriented toward the sun, and for i=1 and 2,

lᵢ≦2\sqrt{(eₜ−eₛᵤₚ)(eₜ−eₛᵤₚ+2Rᵢ)}.

Such a module may find application for a transport vehicle, for a building trade, or street furniture. A roof or part of a roof of a motor vehicle can also include such a module.

The present invention relates to modules containing photovoltaic cells, for which, in particular, ever more complex shapes having small radii of curvature, i.e. having pronounced curvatures, are sought.

In particular the integration of photovoltaic cells of high efficiency, of the type having a rigid support, has never yet been able to be achieved in modules that locally have a curvature along two secant axes.

This problem has now been able to be solved by the invention, one subject of which is a module made of transparent polymer material in which rectangular photovoltaic cells are embedded, which is distinguished by the fact that the sides of said photovoltaic cells have lengths l₁ and l₂ in respective perpendicular directions d₁ and d₂, according to which the module has a curvature of radius R₁, respectively R₂, and by the fact that, if eₜ denotes the total thickness of polymer material and eₛᵤₚ the minimum thickness of polymer material covering the photovoltaic cells of the side intended to be oriented toward the sun, then, for i=1 and 2,

lᵢ≦2\sqrt{(eₜ−eₛᵤₚ)(eₜ−eₛᵤₚ+2Rᵢ)}.

Thus, the invention makes possible the integration of photovoltaic cells, even rigid photovoltaic cells, into modules, at locations having a curvature, even a pronounced curvature, along one or two secant, especially perpendicular, axes.

The module of the invention may geometrically be defined as a sheet having a small thickness compared to its two other dimensions, and the surface of which may have a more or less complex and more or less curved shape. One of the two radii of curvature R₁ or R₂ may be large enough compared to the other so that it is possible to disregard the curvature along the corresponding direction d₁ or d₂ relative to the curvature along the other perpendicular direction, and to consider that the geometry of the module is then of cylindrical curvature (along a single axis).

Any transparent polymer material may constitute the module: polycarbonate (PC), acrylic such as polymethyl methacrylate (PMMA), polyolefin such as polyethylene (PE) or polypropylene (PP), polyamide (PA, especially PA66), polyethylene terephthalate (PET), polyvinyl acetal especially polyvinyl butyral (PVB), polyurethane (PU), copolymer such as acrylonitrile-butadiene-styrene (ABS), ethylene-vinyl acetate (EVA), ionomer resin (ethylene-(meth)acrylic acid copolymer with ionic crosslinking, neutralized by a polyamine), etc., especially those of them which can be injection molded, alone or as a blend of several thereof.

The module of the invention is constituted of a sheet of such a polymer material, especially injection molded, of total thickness eₜ, in which rectangular (or square) photovoltaic cells are embedded. However, this sheet may be assembled to other transparent materials made of mineral or organic glass or non-transparent materials by means of a transparent intermediate adhesive layer such as PVB, PU, EVA or non-transparent intermediate adhesive layer, etc. in order to constitute a module that is laminated and/or with interposition of a gap of dry gas in order to constitute a multiple module, without departing however from the scope of the invention.

However, such optional additional constituents of the module are preferably assembled on the side of the polymer material sheet incorporating photovoltaic cells, which is intended to be on the opposite side to the sun, or optionally on its side intended to be oriented toward the sun on condition that these additional constituents are transparent, allow a large enough portion of the solar radiation to pass through, have a high light transmission and, in particular, are not tinted.

If certain parts of the surface of the module are transparent, it may be called glazing. If, on the other hand, this surface is completely opaque, i.e. if one constituent at least of the module intended to be positioned at the back of the cells relative to the sun, is itself opaque over its entire surface, the module may constitute a body or cowling component of an automotive or other transport vehicle, or for the building trade, etc.

It is specified that in the module the spacings between the photovoltaic cells, g₁ and g₂ along the directions d₁ and d₂ respectively, are any, chosen according to the visual impression that it is desired to obtain on one side or the other of the module. When one part of the surface of the module is transparent, the larger the values of g₁ and g₂ are, the greater the proportion of the surface of the module likely to be transparent. It is thus possible to obtain effects comparable to those of a tinted module, or a shaded module by varying the values of g₁ and/or g₂ over the surface of the module.

The photovoltaic cells have a thickness at most equal to 0.5 mm, considered to be negligible relative to the thickness of the module, which may be of the order of 3-4 mm for example.

They are constituted of an active face firmly attached to a flexible or rigid base.

The latter may be metallic or equivalent, having a thickness between 25 and 500 μm, preferably between 75 and 250 μm, or polymer such as polyimide having a thickness between 13 and 125 μm. Examples thereof are a cell base made of steel
that is flexible, having a thickness of 25 to 200 μm, preferably 100 to 150 μm, or
that is rigid, having a thickness of 100-500 μm, preferably 175 to 225 μm.

The active face of the photovoltaic cells may be constituted of a sheet of amorphous Si having a thickness between 20 and 200 μm and combined for example with a flexible metallic or polymer base, or of a sheet of crystalline Si having a thickness between 100 and 300 μm and combined for example with a rigid metallic base, or alternatively of a thin film of CIGS (Cu In Ga Se) or CdTe type combined with a flexible or rigid, polymer, metallic, etc. base.

However, preferably, at least one of said photovoltaic cells has a rigid support, especially having an active face of monocrystalline or polycrystalline silicon, the efficiency of which is relatively high.

In one preferred embodiment of the module of the invention, the polymer material from which it is formed is a polycarbonate and the minimum thickness of this polymer material covering the photovoltaic cells on the side intended to be oriented toward the sun, eₛᵤₚ, is at least equal to 2.5 mm. This value is particularly recommended when an injection molding of polycarbonate is carried out.

Moreover, in view of the weight, space requirement, etc. considerations, in particular in the field of transport, such as automotive transport, the total thickness of polymer material, eₜ, is advantageously at most equal to 4 mm.

The module of the invention has, at least at one point, a curvature along two perpendicular axes, especially non-infinite values of R₁ and R₂. More specifically, in accordance with one advantageous variant, R₁ and R₂ are at most equal to 2000 mm, preferably 1500 mm and particularly preferably 1000 mm.

One of the curvatures along the direction d₁ or d₂ may preferably be pronounced, which is the expression of a complex shape of the module, by the fact that at least one of the radii of curvature R₁ and R₂ is at most equal to 1000 mm, preferably 750 mm and particularly preferably 500 mm. When one of the two radii of curvature R₁ and R₂ is thus particularly small, the other may be much larger, so that it is possible to consider the curvature at this point to be cylindrical (along a single one of the two directions d₁ or d₂), without departing from the scope of the invention.

In one particular embodiment of the module of the invention, the transparent polymer material in which the cells are embedded constitutes the intermediate adhesive layer of a laminate; this layer may be polyvinyl butyral (PVB), polyurethane (PU), ethylene-vinyl acetate (EVA), etc. This intermediate adhesive layer then joins two sheets of glass, or one sheet of glass and one sheet of another material, for example a polymer such as polycarbonate (PC), polymethyl methacrylate (PMMA), ionomer resin, etc., or else two such sheets of another material. This intermediate adhesive layer of a laminate then has advantageously an acoustic property, in particular when the module is intended to be installed in the roof or windshield of an electric vehicle: the rain for example is then less audible in the passenger compartment.

According to one advantageous feature, the photovoltaic cells are encapsulated in a damping envelope (especially for damping differential linear thermal expansion between the cells and the transparent polymer material in which they are embedded). This damping envelope is constituted, for example, of polycarbonate (PC), polyimide (P1), polyethylene terephthalate (PET), polypropylene (PP), polyethylene (PE), polyurethane (PU), of a fluoropolymer film such as ethylene-tetrafluoroethylene (ETFE), fluoroethylene-propylene (FEP) or equivalent, having a thickness between 13 μm and 2 mm, preferably at most equal to 500 μm. This envelope moreover protects its photovoltaic cell from moisture.

The outer surface of this damping envelope is preferably constituted of the same material as that in which it is intended to be integrated (polycarbonate in the case of the injection molding of polycarbonate, polyvinyl butyral or ethylene-vinyl acetate for example in the case of integration into a laminate).

According to another advantageous feature, the module comprises discretized rigid photovoltaic cells combined with a photovoltaic thin film on a glass or polymer substrate in the regions of most pronounced curvature. These discretized rigid cells are then especially constituted, at least partly, of said rectangular photovoltaic cells of the module of the invention described above, especially of the type having high efficiency. They ensure an adaptation to the curvature, an optimal photovoltaic efficiency in their region and an esthetic and visual control of the luminosity of the side of the module on the opposite side to the solar radiation. The regions of most pronounced curvature may be edge regions; the use of a photovoltaic thin film makes it possible to combine with the increased production of electricity of the discretized rigid photovoltaic cells, a surface of the module having varied and complex curvature. In a laminated module, the photovoltaic thin film is deposited, for example, on an inner face of the laminate.

Other subjects of the invention are:
a process for manufacturing a module as described previously, comprising the positioning of the photovoltaic cells in the cavity of a mould for injection molding of thermoplastic polymer material, then the injection molding thereof;
a process for manufacturing another module as described previously, comprising the incorporation of the photovoltaic cells into the intermediate adhesive layer of a laminate (for example by inserting them between two constituent sheets of this layer) prior to the assembly of the laminate, then this assembly by conventional means (temperature, pressure, vacuum),
the application of this module for a land, air or aquatic transport vehicle, in particular as a roof of a motor vehicle, for the building trade or street furniture (bus shelter, display panels, etc.), either as a partly transparent component, glazing, or as a completely opaque component (body, cowling, etc. component),
a roof or part of a roof of a motor vehicle comprising such a module as described previously.

The invention is now illustrated by the appended drawings in which:

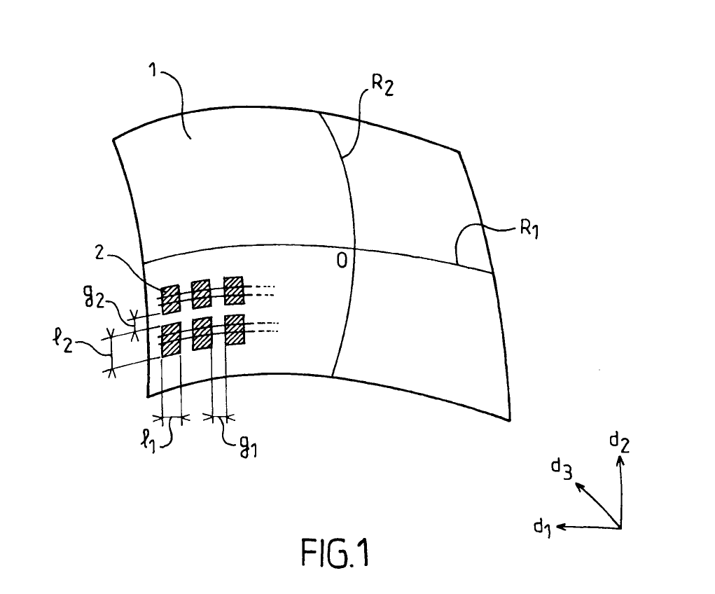

FIG. 1 is a schematic representation, in perspective, of a glazing (partly transparent module) according to the invention, and

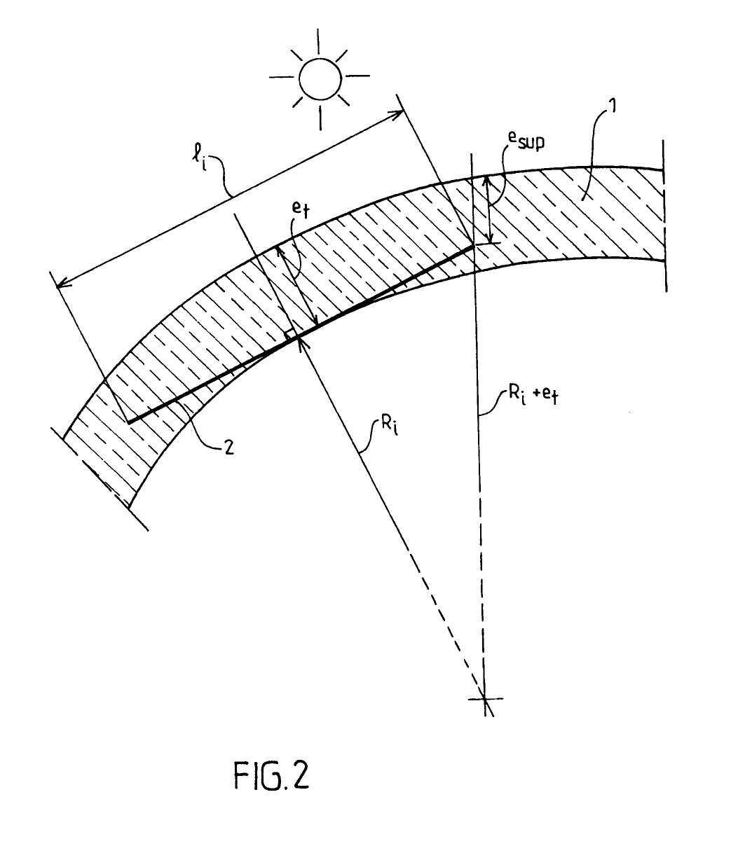

FIG. 2 is a cross-sectional view of this glazing.

With reference to FIGS. 1 and 2 together, the glazing 1 has, for example at point O, a double curvature, with respective radii R₁ and R₂, along two perpendicular planes P₁=(d₁ d₃) and P₂=(d₂ d₃) respectively. The glazing 1 is constituted of a sheet of polycarbonate of thickness eₜ, embedded in which are flat and rigid rectangular photovoltaic cells 2, having active faces made of monocrystalline or polycrystalline silicon.

The thickness of the photovoltaic cells 2 is negligible compared to eₜ. The minimum thickness of polycarbonate covering the photovoltaic cells 2 on the side intended to be oriented toward the sun, is eₛᵤₚ.

Here, Eₜ and Eₛᵤₚ are equal to 4 mm and 2.5 mm respectively.

The maximum values of the dimensions l₁×l₂ of the photovoltaic cells are calculated as a function of the local radii of curvature R₁ and R₂, which are equal, by assumption, to 2027.25 mm and 500 mm respectively.

$${𝓁}_{1} \leq 2 \sqrt{( 4 - 2.5 ) ( 4 - 2.5 + 4054.50 )} \leq 2 \sqrt{1.5 ( 1.5 + 4054.50 )} \leq 2 \sqrt{2.25 + 6081.75} \leq 156 mm .$$

By the same calculation,

$${𝓁}_{2} \leq 2 \sqrt{2.25 + 1500} \leq 77.52 mm .$$

The spacing of the photovoltaic cells, in other words the values of the spacings g₁ and g₂, is chosen as a function of several criteria:
the smaller these values are, the larger the surface for producing electricity is;
but the smaller these values are, the smaller the fraction of the surface of the module capable of allowing a greater portion of the sunlight to pass through.

Thus, when the module is a (partly transparent) glazing as in this example, the choice of the values of g₁ and g₂ has an esthetic incidence (various visual effects such as shading of luminosity, etc.) seen from the side that is on the opposite side to the sun (vehicle passenger compartment, building interior, etc.), whereas when the module is completely opaque, the choice of the values of g₁ and g₂ has an esthetic incidence seen from the sun side.

The electrical connections linking several photovoltaic cells to one another, and these cells to a collector, are not represented.

Thus, rigid photovoltaic cells of high efficiency have been integrated into a glazing of complex shape, via a simple process (injection molding of polycarbonate, lamination, etc.).

1-13. (canceled)

14. A module made of transparent polymer material comprising:
embedded rectangular photovoltaic cells,
wherein sides of the photovoltaic cells have lengths l₁ and l₂ in respective perpendicular directions d₁ and d₂, according to which the module has a curvature of radius R₁, respectively R₂, and
wherein eₜ denotes the total thickness of polymer material and eₛᵤₚ the minimum thickness of polymer material covering the photovoltaic cells of the side intended to be oriented toward the sun, and for i=1 and 2,
lᵢ≦2\sqrt{(eₜ−eₛᵤₚ)(eₜ−eₛᵤₚ+2Rᵢ)}.

15. The module as claimed in claim 14, wherein at least one of the photovoltaic cells has a rigid support.

16. The module as claimed in claim 14, wherein the polymer material is a polycarbonate and the minimum thickness of polymer material covering the photovoltaic cells of the side intended to be oriented toward the sun, eₛᵤₚ, is at least equal to 2.5 mm.

17. The module as claimed in claim 14, wherein the total thickness of polymer material, eₜ, is at most equal to 4 mm.

18. The module as claimed in claim 14, wherein R₁ and R₂ are equal to or less than 2000 mm, or 1500 mm, or 1000 mm.

19. The module as claimed in claim 14, wherein at least one of the radii of curvature R₁ and R₂ is equal to or less than 1000 mm, or 750 mm, or 500 mm.

20. The module as claimed in claim 14, wherein the transparent polymer material constitutes an intermediate adhesive layer of a laminate.

21. The module as claimed in claim 14, wherein the photovoltaic cells are encapsulated in a damping envelope.

22. The module as claimed in claim 14, comprising discretized rigid photovoltaic cells combined with a photovoltaic thin film on a glass or polymer substrate in regions of most pronounced curvature.

23. A process for manufacturing a module as claimed in claim 14, comprising positioning of the photovoltaic cells in a cavity of a mold for injection molding of thermoplastic polymer material, then the injection molding thereof.

24. A process for manufacturing a module as claimed in claim 14, comprising incorporation of the photovoltaic cells into an intermediate adhesive layer of a laminate prior to assembly thereof, then assembly.

25. An application of a module as claimed in claim 14 for a land, air, or aquatic transport vehicle, for a building trade or street furniture.

26. A roof or part of a roof of a motor vehicle comprising a module as claimed in claim 14.
